(19) United States
(12) Patent Application Publication
(10) Pub. No.: US 2007/0150217 A1
(43) Pub. Date: Jun. 28, 2007

(54) Low-voltage detection device and low-voltage detection method

(75) Inventor: Isao Sasazaki, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/373,115

(22) Filed: Mar. 13, 2006

(30) Foreign Application Priority Data
Dec. 22, 2005 (JP) JP2005-370192

(51) Int. Cl. G01R 19/165; G05F 5/00; H02H 3/24

(52) U.S. Cl. 702/64; 361/1; 361/88; 361/90; 361/92; 324/416; 327/540; 702/1; 702/57

(57) ABSTRACT

A threshold value serving as a reference for judging a decrease in power source voltage supplied to a semiconductor device is registered as digital data, detection data corresponding to a magnitude of the power source voltage is outputted by executing an analog/digital conversion of the power source voltage, the threshold value is compared with the detection data, and there is outputted a control signal controlling as to whether or not setting of the semiconductor device should be set in an initial state in accordance with the compared result.

### BACKGROUND OF THE INVENTION

1. Field of the Invention

The present invention relates to a low-voltage detection device and a low-voltage detection method.

2. Description of the Related Art

At the present, an engine control system and a keyless entry system of an automobile are generally mounted with a semiconductor device (which is typically an LSI (Large Scale Integrated circuit) of a microcomputer etc. These systems need preventing the semiconductor device from overrunning due to a drop in power source voltage. Hence, this type of LSI has hitherto been required to receive execution of a process (which will hereinafter be referred to as a low-voltage process) such as detecting, when the power source voltage becomes equal to or smaller than a predetermined magnitude, this decrease in the power source voltage and setting the system back to an initial state (which will hereinafter be termed reset). Accordingly, the semiconductor device has an externally-attached device for detecting the decrease in power source voltage. For instance, it is assumed that 4.0V is used as a threshold value for detecting the low-voltage. In this case, when the power source voltage of the semiconductor device becomes equal to or smaller than 4.0V, there occurs a state where the low-voltage is detected, and the predetermined process such as setting the setting in the initial state, is executed.

The threshold value for setting the semiconductor device in the initial state in accordance with the decrease in power source voltage has hitherto been fixed to one value. Therefore, the semiconductor devices, in which the threshold values of the voltage are respectively set, are required to be manufactured individually in accordance with respective purposes for usage. Considered is, for example, a case in which the semiconductor device is utilized as a key of the automobile. In this case, not an output voltage by a main body of the automobile but an output voltage by a button battery etc is used as a power source voltage of the semiconductor device. The voltage of the battery is generally lower than the output voltage by the main body of the automobile. Hence, there is such a request that it is desirable that the threshold value of the voltage for resetting the semiconductor device can be readily set corresponding to applications of the semiconductor device and the power source voltage on a maker side of an on-vehicle maker etc.

Further, for actualizing this reset function, an external circuit and a plurality of chips have hitherto been connected to a reset-target semiconductor device. For saving the resources and the space as well, however, such a request exits that the reset function be, it is desirable, built in the semiconductor device.

The followings are related arts to the present invention.

[Patent document 1] Japanese Patent Application Laid-Open Publication No. 2002-108510

[Patent document 2] Japanese Patent Application Laid-Open Publication No. 2005-151697

[Patent document 3] Japanese Patent Application Laid-Open Publication No. 2003-32089

### SUMMARY OF THE INVENTION

The application was made in view of the requests given to the related arts. Namely, it is an object of the present invention to provide a technology capable of setting the threshold value for judging the decrease in power source voltage supplied to the semiconductor device according to applications. Further, it is another object to provide a technology capable of getting such a function built in the semiconductor device.

The present invention adopts the following means in order to solve the problems.

(1) Namely, a low-voltage detection device according to the present invention registers, as digital data, a threshold value serving as a reference for judging a decrease in power source voltage supplied to a semiconductor device, executes an A/D (analog/digital) conversion of the power source voltage, outputs detection data corresponding to a magnitude of the power source voltage, compares the threshold value with the detection data, and outputs a control signal for controlling as to whether or not setting of the semiconductor device should be set in an initial state in accordance with the compared result.

With this configuration, the threshold value serving as the reference for judging the decrease in power source voltage supplied to the semiconductor device can be registered as the digital data in the low-voltage detection device. The low-voltage detection device executes the A/D (analog/digital) conversion of the power source voltage and outputs the detection data corresponding to the magnitude of the power source voltage. The low-voltage detection device compares the threshold value serving as the reference for judging the decrease in power source voltage with the detection data corresponding to the magnitude of the power source voltage, and outputs the control signal for controlling as to whether or not setting of the semiconductor device should be set in the initial state in accordance with the compared result. Thus, the low-voltage detection device can register the threshold value serving as the reference for judging the decrease in power source voltage supplied to the semiconductor device and can set the setting of the semiconductor device in the initial state in accordance with the registered threshold value.

(2) Further, a low-voltage detection device according to the present invention may register, as digital data, a threshold value serving as a reference for judging a decrease in power source voltage supplied to a semiconductor device, execute an analog/digital conversion of the threshold value, output a voltage corresponding the threshold value, compare the voltage corresponding to the threshold value with the power source voltage, and output a control signal for controlling as to whether or not setting of the semiconductor device should be set in an initial state in accordance with the compared result.

With this configuration, the threshold value serving as the reference for judging the decrease in power source voltage supplied to the semiconductor device can be registered as the digital data in the low-voltage detection device. The low-voltage detection device executes the D/A (digital/analog) conversion of the threshold value serving as the reference for judging the decrease in power source voltage, and outputs the voltage corresponding to the threshold value. The low-voltage detection device compares the threshold value serving as the reference for judging the decrease in power source voltage with the power source voltage, and outputs the control signal for controlling as to whether or not setting of the semiconductor device should be set in the initial state in accordance with the compared result. Thus, the low-voltage detection device can register the threshold value serving as the reference for judging the decrease in power source voltage supplied to the semiconductor device and can set the setting of the semiconductor device in the initial state in accordance with the registered threshold value.

(3) Moreover, a low-voltage detection device according to the present invention may output a second control signal that sets the setting of the semiconductor device in the initial state for a predetermined period of time from just after power-on of the power source voltage and gets the setting of the semiconductor device transitioning from the initial state after the predetermined period of time.

With this configuration, the low-voltage detection device can output the signal that sets the setting of the semiconductor device in the initial state for the predetermined period of time from just after power-on of the power source voltage.

(4) Still further, the low-voltage detection device according to the present invention may detect the power source voltage and output a signal that sets, when the detected power source voltage does not reach a predetermined value, the setting of the semiconductor device in the initial state independently of the control signal.

With this configuration, the low-voltage detection device detects the power source voltage. The low-voltage detection device can set, when the detected power source voltage does not reach the predetermined value, the setting of the semiconductor device in the initial state.

(5) Yet further, the low-voltage detection device according to the present invention may accept one or more inputs of the signals that control as to whether or not the setting of the semiconductor device should be set in the initial state and output, when one of the accepted signals is a signal that sets the setting of the semiconductor device in the initial state, the signal that sets the setting of the semiconductor device in the initial state.

With this configuration, the low-voltage detection device accepts one or more inputs of the signals that control as to whether or not the setting of the semiconductor device should be set in the initial state. The low-voltage detection device can, when one of the accepted signals is the signal that sets the setting of the semiconductor device in the initial state, set the setting of the semiconductor device in the initial state. Thus, the low-voltage detection device can, when there are one or more signals that set the setting of the semiconductor device in the initial state, set the setting of the semiconductor device in the initial state.

(6) Moreover, the low-voltage detection device according to the present invention may input the signal that controls as to whether or not the setting of the semiconductor device should be set in the initial state, set the setting of the semiconductor device in the initial state when the inputted signal is the signal that sets the setting of the semiconductor device in the initial state and when the setting of the semiconductor device is not in the initial state, continue the initial state of the semiconductor device when the inputted signal is the signal that sets the setting of the semiconductor device in the initial state and when the setting of the semiconductor device is in the initial state, continue the setting of the semiconductor device when the inputted signal is a signal showing that the setting of the semiconductor device is not set in the initial state and when the setting of the semiconductor device is not in the initial state, and cancel the initial state of the semiconductor device when the inputted signal is the signal showing that the setting of the semiconductor device is not set in the initial state and when the setting of the semiconductor device is in the initial state.

With this configuration, the low-voltage detection device can control as to whether or not the setting of the semiconductor device is set in the initial state, corresponding to the input of the signal that controls as to whether the setting of the semiconductor device is set in the initial state.

The present invention may also be a low-voltage detection method for executing the processes given above.

According to the present invention, the threshold value for judging the decrease in power source voltage supplied to the semiconductor device can be set corresponding to the applications. Further, according to the present invention, such a function can be built in the semiconductor device.

### BRIEF DESCRIPTION OF THE DRAWINGS

FIG. 1 is a diagram showing a basic configuration of a low-voltage detection device in a first embodiment of the present invention;

FIG. 2 is a diagram showing a configuration of an A/D converter in the first embodiment of the present invention;

FIG. 3 is a diagram showing an example of a logic value table stored in a comparing unit according to the first embodiment of the present invention;

FIG. 4 is a diagram showing a basic configuration of the low-voltage detection device in a second embodiment of the present invention;

FIG. 5 is a diagram showing a basic configuration of the low-voltage detection device in a third embodiment of the present invention; and

FIG. 6 is a diagram showing an example of a configuration of a D/A converter according to the third embodiment of the present invention.

### DETAILED DESCRIPTION OF THE PREFERRED EMBODIMENT

Embodiments of the present invention will hereinafter be described with reference to the drawings. Configurations in the following embodiments are exemplifications, and the present invention is not limited to the configurations in the embodiments.

### First Embodiment

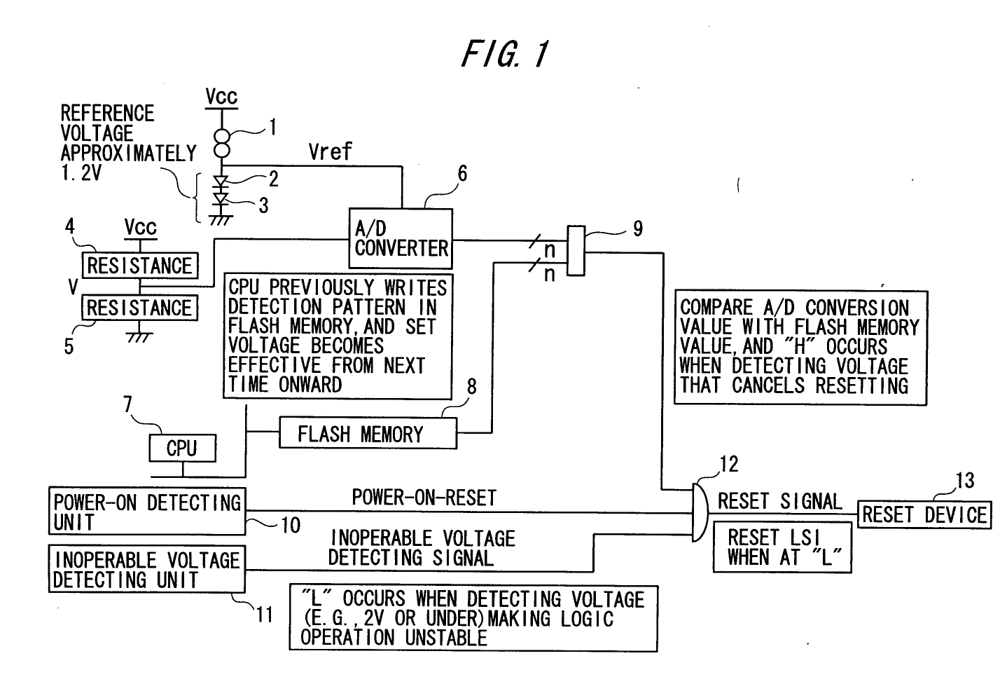

A low-voltage detection device in a first embodiment of the present invention will hereinafter be explained with reference to the drawings in FIGS. 1 through 3. The low-voltage detection device includes a diode 2 connected to a constant current source 1 connected to a power source voltage Vcc, a diode 3 connected to the diode 2 and to the earth, a resistance 4 connected to the power source voltage, a resistance 5 connected to the resistance 4 and to the earth, an A/D converter 6 connected to the constant current source 1, to the diode 2, to the resistance 4 and to the resistance 5, a flash memory 8 connected to a CPU 7, a comparing unit 9 connected to the A/D converter 6 and to the flash memory 8, a signal integrator 12 connected to the comparing unit 9, to a power-on detecting unit 10 and to an inoperable voltage detecting unit 11, and a reset device 13 connected to the signal integrator 12. The resistance 4 and the resistance 5 shall be resistances each having a magnitude “R”.

To begin with, the CPU 7 receives, from a user, designation of a threshold value of the voltage by which to execute resetting an LSI. The CPU 7, upon receiving the designation, converts this designation into a bit pattern (detection pattern) and registers the detection pattern in the flash memory 8. For example, [HHLL] is given as a detection pattern. This registration process is executed by the CPU 7 executing a program stored in the flash memory 8. The CPU 7 and the flash memory 8 correspond to a “registering unit” according to the present invention. Further, the flash memory 8 may have a default detection pattern. The flash memory 8 has the default detection pattern, whereby the low-voltage detection device can execute resetting the LSI when the power source voltage becomes equal to or smaller than a magnitude of a predetermined voltage designated by the default detection pattern without the user's designating the threshold value of the voltage by which to execute resetting the LSI.

A voltage between the constant current source 1 and the diode 2 is set as a comparative voltage Vref. The comparative voltage Vref is a fixed voltage that is hard to depend on a change in magnitude of the power source voltage Vcc by the constant current source 1, the diode 2 and the diode 3. To give an example, forward voltages of the diode 2 and the diode 3 are each set to 0.6V. Then, the comparative voltage Vref comes to 1.2V. This comparative voltage Vref is inputted to the A/D converter 6.

Further, a voltage between the resistance 4 and the resistance 5 is set as V. A magnitude of the voltage V is Vcc/2. The voltage V is inputted to the A/D converter 6 and becomes an object of the low-voltage detection (i.e., an object of detection as to whether equal to or smaller than the voltage for starting up a low-voltage process). The A/D converter 6, upon the inputs of the comparative voltage Vref and the voltage V, converts, based of the comparative voltage Vref, the voltage V related to the power source voltage into the bit pattern. For instance, [HLLL] is given as a bit pattern. The A/D converter 6 outputs the bit pattern to the comparing unit 9. The A/D converter 6 corresponds to a “bit pattern outputting unit” according to the present invention.

Inputted to the comparing unit 9 are the bit pattern form the A/D converter 6 and the detection pattern from the flash memory 8. The comparing unit 9 outputs a signal [L] or a signal [H] to the signal integrator 12, corresponding to the inputted bit pattern and the inputted detection pattern. The comparing unit 9 corresponds to a “control unit” according to the present invention. For example, the comparing unit 9 compares the inputted bit pattern [HLLL] with the detection pattern [HHLL], and outputs the signal [L] or the signal [H] to the signal integrator 12, corresponding to a compared result.

The power-on detecting unit 10 keeps outputting the signal [L] to the signal integrator 12 for a predetermined period of time till the magnitude of the power source voltage becomes equal to or larger than a predetermined magnitude from just after power-on. The power-on detecting unit 10 outputs the signal [H] to the signal integrator 12 after the predetermined time. The signal [L] implies the execution of resetting the LSI, i.e. implies initializing a state of the setting of the LSI. The signal [H] implies what excludes the execution of resetting the LSI. For instance, the signal [H] is a signal for having the LSI operated as it is without the execution of resetting the LSI. Alternatively, if the LSI is in the reset state, the signal [H] is a signal for setting the LSI in the operating state. Accordingly, the power-on detecting unit 10 executes resetting the LSI for the predetermined period of time from just after the power-on. The power-on detecting unit 10 corresponds to a “second control unit” according to the present invention.

The inoperable voltage detecting unit 11 detects the power source voltage. The inoperable voltage detecting unit 11, when judging that the magnitude of the detected voltage is equal to or smaller than the predetermined magnitude, outputs the signal [L] to the signal integrator 12. The inoperable voltage detecting unit 11, when judging that the magnitude of the detected voltage is larger than the predetermined magnitude, outputs the signal [H] to the signal integrator 12. When the power source voltage for a logic unit (logic circuit) built in the comparing unit 9 etc becomes equal to or smaller than the predetermined magnitude, the low-voltage detection device gets inconstant of outputting. The inoperable voltage detecting unit 11, when the power source voltage becomes equal to or smaller than the predetermined magnitude, serves to forcibly execute resetting the LSI. The inoperable voltage detecting unit 11 corresponds to a “third control unit” according to the present invention.

Inputted to the signal integrator 12 is any one of the signal [L] and the signal [H] from the comparing unit 9, the power-on detecting unit 10 and the inoperable voltage detecting unit 11, respectively. The signal integrator 12, when there is at least one signal [L] in the signals inputted from the comparing unit 9, the power-on detecting unit 10 and the inoperable voltage detecting unit 11, outputs the signal [L] to the reset device 13. The signal integrator 12, when there is none of the signal [L] in these signals, outputs the signal [H] to the reset device 13. The signal integrator 12 corresponds to a “fourth control unit” according to the present invention.

The reset device 13, when the signal [L] is inputted from the signal integrator 12, executes resetting the LSI connected to the reset device 13. Further, the reset device 13, when the signal [H] is inputted from the signal integrator 12, does not execute resetting the LSI. Moreover, after the resetting of the LSI once has been executed, if the input of the signal [L] continues, the LSI stops in the reset state. Then, the reset device 13, when the signal [H] is inputted, cancels the reset state.

In the way described above, the low-voltage detection device registers the detection pattern for designating the threshold value of the voltage by which to reset the LSI, effects the A/D (analog/digital) conversion of the power source voltage, outputs the bit pattern corresponding to the magnitude of the power source voltage, compares the registered detection pattern with the outputted bit pattern, resets the LSI in accordance with the compared result, and can continue the reset or can cancel the reset state.

As described above, the reset of the LSI is executed, wherein the magnitude of the voltage set in the flash memory 8, which can be built in the LSI, is set as the threshold value. Moreover, the low-voltage detection device may also be built in one LSI, including other components of this low-voltage detection device.

Furthermore, it is possible for the CPU 7 to set, in the flash memory 8, a plurality of threshold values, each serving to judge a decrease in the power source voltage, of the voltage for detecting the low-voltage detection in the single LSI. Accordingly, there is no necessity of manufacturing the LSIs respectively for the LSI applications and for the utilizable power source voltages.

<Example of Configuration of A/D Converter>

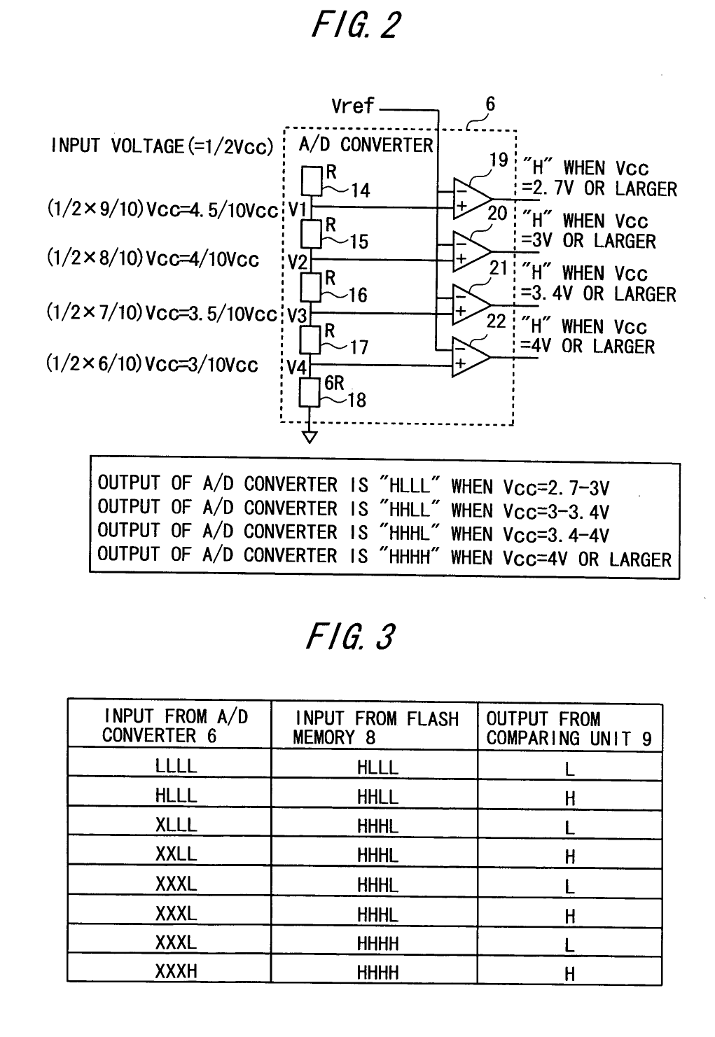

The A/D converter 6 included in the low-voltage detection device according to a first embodiment will hereinafter be described with reference to the drawing in FIG. 2. The A/D converter 6 has a resistance 14 connected to an input voltage of Vcc/2, a resistance 15 connected to the resistance 14, a resistance 16 connected to the resistance 15, a resistance 17 connected to the resistance 16, a resistance 18 connected to the resistance 17, a comparator 19 connected to the resistance 14, to the resistance 15 and to the comparative voltage Vref, a comparator 20 connected to the resistance 15, to the resistance 16 and to the comparative voltage Vref, a comparator 21 connected to the resistance 16, to the resistance 17 and to the comparative voltage Vref, and a comparator 22 connected to the resistance 17, to the resistance 18 and to the comparative voltage Vref. Each of the resistances 14 through 17 shall be set as a resistance having a magnitude of R. The resistance 18 shall be set as a resistance having a magnitude of 6R.

A voltage between the resistance 14 and the resistance 15 shall be set as V1. The voltage V1 is a magnitude that is 9/20 the power source voltage Vcc. The voltage V1 is inputted to the comparator 19. The comparator 19 compares the voltage V1 with the comparative voltage Vref (1.2V). When the voltage V1 is larger than the comparative voltage Vref, the comparator 19 outputs the signal [H] to a comparing unit 10. Further, when the voltage V1 is smaller than the comparative voltage Vref, the comparator 19 outputs the signal [L] to the comparing unit 10. The comparison between the voltage V1 and the power source voltage Vcc by the comparator 19 can be considered to be a comparison between the power source voltage Vcc and a voltage (2.7V) having a magnitude that is 20/9 the comparative voltage Vref.

A voltage between the resistance 15 and the resistance 16 shall be set as V2. The voltage V2 is a magnitude that is 8/20 the power source voltage Vcc. The voltage V2 is inputted to the comparator 20. The comparator 20 compares the voltage V2 with the comparative voltage Vref. When the voltage V2 is larger than the comparative voltage Vref, the comparator 20 outputs the signal [H] to the comparing unit 10. Further, when the voltage V2 is smaller than the comparative voltage Vref, the comparator 20 outputs the signal [L] to the comparing unit 10. The comparison between the voltage V2 and the power source voltage Vcc by the comparator 20 can be considered to be a comparison between the power source voltage Vcc and a voltage (3.0V) having a magnitude that is 20/8 the comparative voltage Vref.

A voltage between the resistance 16 and the resistance 17 shall be set as V3. The voltage V3 is a magnitude that is 7/20 the power source voltage Vcc. The voltage V3 is inputted to the comparator 21. The comparator 21 compares the voltage V3 with the comparative voltage Vref. When the voltage V3 is larger than the comparative voltage Vref, the comparator 21 outputs the signal [H] to the comparing unit 10. Further, when the voltage V3 is smaller than the comparative voltage Vref, the comparator 21 outputs the signal [L] to the comparing unit 10. The comparison between the voltage V3 and the power source voltage Vcc by the comparator 21 can be considered to be a comparison between the power source voltage Vcc and a voltage (3.4V) having a magnitude that is 20/7 the comparative voltage Vref.

A voltage between the resistance 17 and the resistance 18 shall be set as V4. The voltage V4 is a magnitude that is 6/20 the power source voltage Vcc. The voltage V4 is inputted to the comparator 22. The comparator 22 compares the voltage V4 with the comparative voltage Vref. When the voltage V4 is larger than the comparative voltage Vref, the comparator 22 outputs the signal [H] to the comparing unit 10. Further, when the voltage V4 is smaller than the comparative voltage Vref, the comparator 22 outputs the signal [L] to the comparing unit 10. The comparison between the voltage V4 and the power source voltage Vcc by the comparator 22 can be considered to be a comparison between the power source voltage Vcc and a voltage (4.0V) having a magnitude that is 20/6 the comparative voltage Vref.

Thus, the A/D converter 6, when the power source voltage Vcc is smaller than 2.7V, outputs the signal [LLLL] to the comparing unit 9. The A/D converter 6, when the power source voltage Vcc is 2.7V through 3.0V, outputs the signal [HLLL] to the comparing unit 9. The A/D converter 6, when the power source voltage Vcc is 3.0V through 3.4V, outputs the signal [HHLL] to the comparing unit 9. The A/D converter 6, when the power source voltage Vcc is 3.4V through 4.0V, outputs the signal [HHHL] to the comparing unit 9. The A/D converter 6, when the power source voltage Vcc is larger than 4.0V, outputs the signal [HHHH] to the comparing unit 9.

<Example of Logic Table of Comparing Unit>

Types of the signals outputted by the comparing unit 9 according to the first embodiment will hereinafter be explained with reference to the drawing in FIG. 3.

The comparing unit 9, when receiving an input of the signal [LLLL] as an input from the A/D converter 6 and an input of the signal [HLLL] as an input from the flash memory 8, outputs the signal [L] to the signal integrator 12.

The comparing unit 9, when receiving an input of the signal [HLLL] as the input from the A/D converter 6 and an input of the signal [HLLL] as the input from the flash memory 8, outputs the signal [H] to the signal integrator 12.

The comparing unit 9, when receiving an input of the signal [XLLL] as the input from the A/D converter 6 and an input of the signal [HHLL] as the input from the flash memory 8, outputs the signal [L] to the signal integrator 12. Herein, it is assumed that [X] may take a value of either [H] or [L].

The comparing unit 9, when receiving an input of the signal [XHLL] as the input from the A/D converter 6 and an input of the signal [HLLL] as the input from the flash memory 8, outputs the signal [H] to the signal integrator 12.

The comparing unit 9, when receiving an input of the signal [XXLL] as the input from the A/D converter 6 and an input of the signal [HHHL] as the input from the flash memory 8, outputs the signal [L] to the signal integrator 12.

The comparing unit 9, when receiving an input of the signal [XXHL] as the input from the A/D converter 6 and an input of the signal [HHHL] as the input from the flash memory 8, outputs the signal [H] to the signal integrator 12.

The comparing unit 9, when receiving an input of the signal [XXXL] as the input from the A/D converter 6 and an input of the signal [HHHH] as the input from the flash memory 8, outputs the signal [L] to the signal integrator 12.

The comparing unit 9, when receiving an input of the signal [XXXH] as the input from the A/D converter 6 and an input of the signal [HHHH] as the input from the flash memory 8, outputs the signal [H] to the signal integrator 12.

Thus, the comparing unit 9 outputs the signals [L] or [H] to the signal integrator 12, corresponding to the input from the A/D converter 6 and the input from the flash memory 8.

<Concerning Registerable Count of Threshold Values of Voltage>

On such an occasion that the CPU 7 registers the threshold value of the voltage in the flash memory 8, a registerable count thereof depends on a bit count of the bit pattern outputted from the A/D converter 6. Considered is, for example, a case in which the signal containing 3-bit information such as the signal [HHL] is outputted as an output signal to the comparing unit 9 from the A/D converter 6. In this case, up to three pieces of magnitudes of the voltage can be registered in the flash memory 8. Considered next is a case in which the signal containing 4-bit information such as the signal [HHHH] is outputted as an output signal to the comparing unit 9 from the A/D converter 6. In this case, up to four pieces of magnitudes of the voltage can be registered in the flash memory 8. Thus, as the bit count of the information contained in the signal outputted to the comparing unit 9 from the A/D converter 6 becomes larger, the registerable count of the threshold values of the voltage gets greater.

In the first embodiment, the flash memory 8 is employed as one of storage mediums. The embodiment of the present invention is not, however, limited to this configuration. For instance, the storage medium may also be EEPROM (Electrically Erasable Programmable Read-Only memory). In short, it may be sufficient to use a rewritable nonvolatile memory.

### Second Embodiment

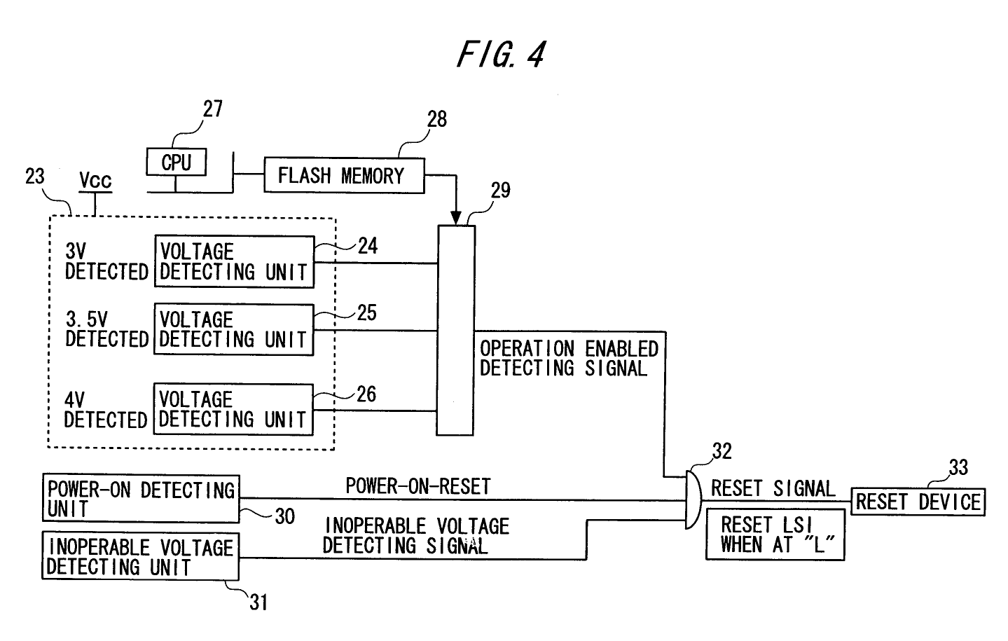

A low-voltage detection device in a second embodiment of the present invention will hereinafter be explained with reference to the drawing in FIG. 4. The low-voltage detection device includes a voltage detection integrating unit 23 connected to the power source voltage Vcc, a flash memory 28 connected to a CPU 27, a multiplexer 29 connected to the voltage detection integrating unit 23 and to the flash memory 28, a power-on detection unit 30, an inoperable voltage detecting unit 31, a signal integrator 32 connected to the multiplexer 29, to the power-on detection unit 30 and to the inoperable voltage detecting unit 31, and a reset device 33 connected to the signal integrator 32. The voltage detection integrating unit 23 includes voltage detecting units 24, 25 and 26. This low-voltage detection device is built in the LSI.

To start with, the CPU 27 receives, from the user, designation of a threshold value of the voltage by which to execute resetting the LSI. The CPU 27, upon receiving the designation, converts this designation into a bit pattern (detection pattern) and registers the detection pattern in the flash memory 28. For example, [HLL] is given as a detection pattern. This registration process is executed by the CPU 27 executing a program stored in the flash memory 28. The CPU 27 and the flash memory 28 correspond to a “registering unit” according to the present invention. Further, the flash memory 28 may have a default detection pattern. The flash memory 28 has the default detection pattern, whereby the low-voltage detection device can execute resetting the LSI when the power source voltage becomes equal to or smaller than a magnitude of a predetermined voltage designated by the default detection pattern without the user's designating the threshold value of the voltage by which to execute resetting the LSI.

The voltage detecting unit 24 detects the power source voltage Vcc. The voltage detecting unit 24, when judging that the detected voltage is equal to or lower than 3V, outputs the signal [L] to the multiplexer 29. The voltage detecting unit 24, when judging that the detected voltage is larger than 3V, outputs the signal [H] to the multiplexer 29.

The voltage detecting unit 25 detects the power source voltage Vcc. The voltage detecting unit 25, when judging that the detected voltage is equal to or lower than 3.5V, outputs the signal [L] to the multiplexer 29. The voltage detecting unit 25, when judging that the detected voltage is larger than 3.5V, outputs the signal [H] to the multiplexer 29.

The voltage detecting unit 26 detects the power source voltage Vcc. The voltage detecting unit 26, when judging that the detected voltage is equal to or lower than 4V, outputs the signal [L] to the multiplexer 29. The voltage detecting unit 26, when judging that the detected voltage is larger than 4V, outputs the signal [H] to the multiplexer 29.

Thus, the voltage detection integrating unit 23 detects the power source voltage and outputs the signal corresponding to the detected voltage to the multiplexer 29. For instance, when the voltage detection integrating unit 23 detects the voltage of 3V, the signal [LLL] is inputted to the multiplexer 29. When the voltage detection integrating unit 23 detects the voltage of 3.5V, the signal [HLL] is inputted to the multiplexer 29. When the voltage detection integrating unit 23 detects the voltage of 4V, the signal [HHL] is inputted to the multiplexer 29. When the voltage detection integrating unit 23 detects a voltage larger than 4V, the signal [HHH] is inputted to the multiplexer 29. The voltage detection integrating unit 23 corresponds to a “bit pattern outputting unit” according to the present invention.

Inputted to the multiplexer 29 are the registered detection pattern from the flash memory 28 and the signal corresponding to the magnitude of the power source voltage from the voltage detection integrating unit 23. The multiplexer 29 judges whether or not the two inputted signals are equal to each other. Furthermore, the multiplexer 29 outputs a different signal to the signal integrator 32, depending on whether the judged signals are equal or not. For example, the multiplexer 29, when judging that one inputted signal is [HHL] and the other signal is [HHL], outputs the signal [L] to the signal integrator 32. Moreover, the multiplexer 29, when judging that one inputted signal is [HHL] and the other signal is [LLL], outputs the signal [H] to the signal integrator 32. Thus, the multiplexer 29, when judging that the two inputted signals are equal to each other, outputs the signal [L] to the signal integrator 32. Moreover, the multiplexer 29, when judging that the two inputted signals are different from each other, outputs the signal [H] to the signal integrator 32. The multiplexer 29 corresponds to a “control unit” according to the present invention.

The power-on detection unit 30 keeps outputting the signal [L] to the signal integrator 32 for a predetermined period of time till the magnitude of the power source voltage becomes equal to or larger than a predetermined magnitude from just after power-on. The power-on detecting unit 30 outputs the signal [H] to the signal integrator 32 after the predetermined period of time. Accordingly, the power-on detecting unit 30 executes resetting the LSI for the predetermined period of time from just after the power-on. The power-on detecting unit 30 corresponds to a “second control unit” according to the present invention.

The inoperable voltage detecting unit 31 detects the power source voltage. The inoperable voltage detecting unit 31, when judging that the magnitude of the detected voltage is equal to or smaller than the predetermined magnitude, outputs the signal [L] to the signal integrator 32. The inoperable voltage detecting unit 31, when judging that the magnitude of the detected voltage is larger than the predetermined magnitude, outputs the signal [H] to the signal integrator 32. When the power source voltage for a logic unit built in the multiplexer 29 etc becomes equal to or smaller than the predetermined magnitude, the low-voltage detection device gets inconstant of outputting. The inoperable voltage detecting unit 31, when the power source voltage becomes equal to or smaller than the predetermined magnitude, serves to forcibly execute resetting the LSI. The inoperable voltage detecting unit 31 corresponds to a “third control unit” according to the present invention.

Inputted to the signal integrator 32 are the signals from the multiplexer 29, the power-on detecting unit 30 and the inoperable voltage detecting unit 31, respectively. The signal integrator 32, when there is at least one signal [L] in these signals, outputs the signal [L] to the reset device 33. The signal integrator 32, when there is none of the signal [L] in these signals, outputs the signal [H] to the reset device 33. The signal integrator 32 corresponds to a “fourth control unit” according to the present invention.

The reset device 33, when the signal [L] is inputted from the signal integrator 32, executes resetting the LSI connected to the reset device 33. Further, the reset device 33, when the signal [H] is inputted from the signal integrator 32, does not execute resetting the LSI. Moreover, after the resetting of the LSI once has been executed, if the input of the signal [L] continues, the LSI stops in the reset state. Then, the reset device 33, when the signal [H] is inputted, cancels the reset state.

In the way described above, the low-voltage detection device registers the detection pattern for designating the threshold value of the voltage by which to reset the LSI, effects the A/D (analog/digital) conversion of the power source voltage, outputs the bit pattern corresponding to the magnitude of the power source voltage, compares the registered detection pattern with the outputted bit pattern, resets the LSI in accordance with the compared result, and can continue the reset or can cancel the reset state.

As described above, the reset of the LSI is executed, wherein the magnitude of the voltage set in the flash memory 28, which can be built in the LSI, is set as the threshold value. Moreover, the low-voltage detection device may also be built in one LSI, including other components of this low-voltage detection device.

Furthermore, the CPU 27 sets, in the flash memory 28, the voltage by which to reset the LSI, thereby making it possible to set a plurality of threshold values of the voltage for detecting the low-voltage detection in the single LSI. Accordingly, there is no necessity of manufacturing the LSIs respectively for the LSI applications and for the utilizable power source voltages.

<Concerning Registerable Count of Threshold Values of Voltage>

A registerable count, with which the CPU 27 registers the threshold value of the voltage in the flash memory 28, depends on a bit count of the bit pattern outputted from the voltage detection integrating unit 23. Considered is, for example, a case in which the signal containing 3-bit information such as the signal [HHL] is outputted as an output signal to the multiplexer 29 from the voltage detection integrating unit 23. In this case, up to three pieces of magnitudes of the voltage can be registered in the flash memory 28. Considered next is a case in which the signal containing 4-bit information such as the signal [HHHH] is outputted as an output signal to the multiplexer 29 from the voltage detection integrating unit 23. In this case, up to four pieces of magnitudes of the voltage can be registered in the flash memory 28. Thus, as the bit count of the information contained in the signal outputted to the multiplexer 29 from the voltage detection integrating unit 23 becomes larger, the registerable count of the threshold values of the voltage gets greater.

### Third Embodiment

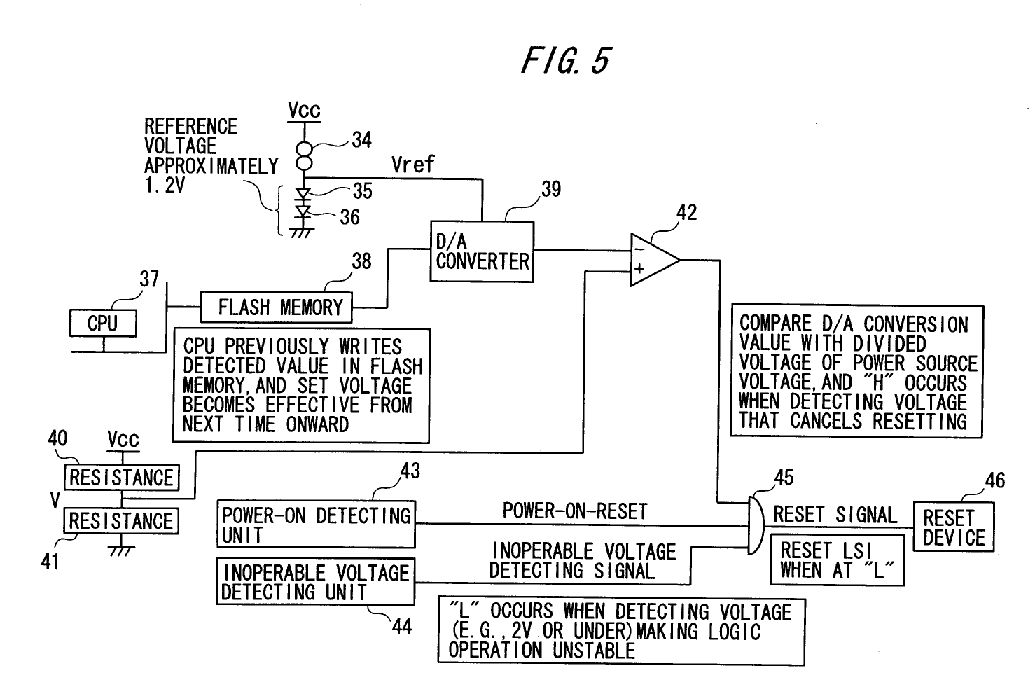

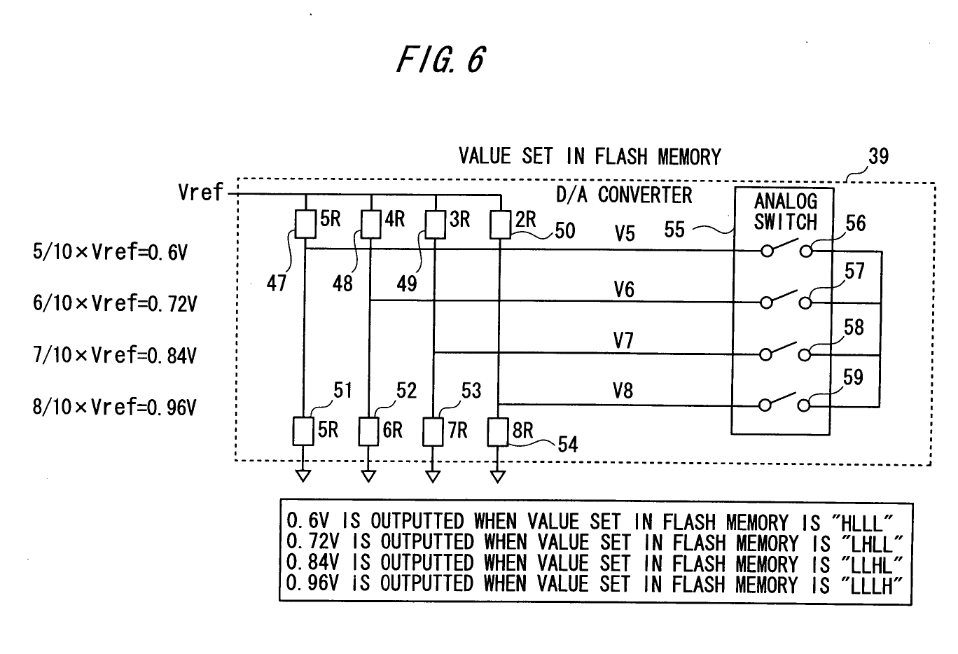

A low-voltage detection device in a third embodiment of the present invention will hereinafter be explained with reference to the drawings in FIGS. 5 and 6. This low-voltage detection device includes a constant current source 34 connected to the power source voltage Vcc, a diode 35 connected to the constant current source 34, a diode 36 connected to the diode 35 and to the earth, a CPU (Central Processing Unit) 36, a flash memory 38 connected to the CPU 37, a D/A converter 39 connected to the constant current source 34, to the diode 35 and to the flash memory 38, a resistance 40 connected to the power source voltage, a resistance 41 connected to the resistance 40 and to the earth, a comparator 42 connected to the resistance 40, to the resistance 41 and to the D/A converter 39, a signal integrator 45 connected to the comparator 42, to a power-on detection unit 43 and to an inoperable voltage detecting unit 44, and a reset device 46 connected to the signal integrator 45. The resistance 40 shall be set as a resistance having a magnitude of 4R, and the resistance 41 shall be set as a resistance having a magnitude of R. This low-voltage detection device is built in the LSI.

At first, the CPU 37 receives, from the user, designation of a threshold value of the voltage by which to execute resetting the LSI. The CPU 37, upon receiving the designation, converts this designation into a bit pattern (detection pattern) and registers the detection pattern in the flash memory 38. For example, [LHLL] is given as a detection pattern. This registration process is executed by the CPU 37 executing a program stored in the flash memory 38. The CPU 37 and the flash memory 38 correspond to a “registering unit” according to the present invention. Further, the flash memory 38 may have a default detection pattern. The flash memory 38 has the default detection pattern, whereby the low-voltage detection device can execute resetting the LSI when the power source voltage becomes equal to or smaller than a magnitude of a predetermined voltage designated by the default detection pattern without the user's designating the threshold value of the voltage by which to execute resetting the LSI.

A voltage between the constant current source 34 and the diode 35 is set as a comparative voltage Vref. The comparative voltage Vref is a fixed voltage that is hard to depend on a change in magnitude of the power source voltage Vcc by the constant current source 34, the diode 35 and the diode 36. To give an example, the comparative voltage Vref is set to approximately 1.2V. The comparative voltage Vref is inputted to the D/A converter 39. On the other hand, the detection pattern is inputted to the D/A converter 39 from the flash memory 38. The D/A converter 39 outputs, to the comparator 42, a voltage corresponding to the inputted detection pattern with respect to the inputted comparative voltage. The D/A converter 39 corresponds to a “voltage outputting unit” according to the present invention.

A voltage between the resistance 40 and the resistance 41 is set as V. A magnitude of the voltage V is Vcc/5. The voltage V is inputted to the comparator 42. The comparator 42 compares the inputted two voltages with each other, i.e., compares the voltage V related to the power source voltage with the comparative voltage Vref. Then, the comparator 42 outputs the signal [H] or [L] to the signal integrator 45, corresponding to the compared result. For instance, the comparator 42, when a magnitude of the voltage inputted from the D/A converter 39 is larger than a magnitude of the voltage V, outputs the signal [L] to the signal integrator 45. Moreover, the comparator 42, when the magnitude of the voltage inputted from the D/A converter 39 is smaller than the magnitude of the voltage V, outputs the signal [H] to the signal integrator 45. The comparator 42 corresponds to a “control unit” according to the present invention.

The power-on detection unit 43 keeps outputting the signal [L] to the signal integrator 45 for a predetermined period of time till the magnitude of the power source voltage becomes equal to or larger than a predetermined magnitude from just after power-on. The power-on detecting unit 43 outputs the signal [H] to the signal integrator 45 after the predetermined period of time. Accordingly, the power-on detecting unit 43 executes resetting the LSI for the predetermined period of time from just after the power-on. The power-on detecting unit 43 corresponds to a “second control unit” according to the present invention.

The inoperable voltage detecting unit 44 detects the power source voltage. The inoperable voltage detecting unit 44, when judging that the magnitude of the detected voltage is equal to or smaller than the predetermined magnitude, outputs the signal [L] to the signal integrator 45. The inoperable voltage detecting unit 44, when judging that the magnitude of the detected voltage is larger than the predetermined magnitude, outputs the signal [H] to the signal integrator 45. When the power source voltage for a logic unit built in the comparator 42 etc becomes equal to or smaller than the predetermined magnitude, the low-voltage detection device gets inconstant of outputting. The inoperable voltage detecting unit 44, when the power source voltage becomes equal to or smaller than the predetermined magnitude, serves to forcibly execute resetting the LSI. The inoperable voltage detecting unit 44 corresponds to a “third control unit” according to the present invention.

Inputted to the signal integrator 45 are the signals from the comparator 42, the power-on detecting unit 43 and the inoperable voltage detecting unit 44, respectively. The signal integrator 45, when there is at least one signal [L] in these signals, outputs the signal [L] to the reset device 46. The signal integrator 45, when there is none of the signal [L] in these signals, outputs the signal [H] to the reset device 46. The signal integrator 46 corresponds to a “fourth control unit” according to the present invention.

The reset device 46, when the signal [L] is inputted from the signal integrator 45, executes resetting the LSI connected to the reset device 46. Further, the reset device 46, when the signal [H] is inputted from the signal integrator 45, does not execute resetting the LSI. Moreover, after the resetting once has been executed, if the input of the signal [L] continues, the LSI stops in the reset state. Then, the reset device 46, when the signal [H] is inputted, cancels the reset state.

In the way described above, the low-voltage detection device registers the detection pattern for designating the threshold value of the voltage by which to reset the LSI, effects the D/A (digital/analog) conversion of the value of the registered detection pattern, outputs the voltage corresponding to the detection pattern, compares the magnitude of the power source voltage with the magnitude of the outputted voltage in their magnitude relationship, resets the LSI in accordance with the compared result, and can continue the reset or can cancel the reset state.

As described above, the reset of the LSI is executed, wherein the magnitude of the voltage set in the flash memory 38, which can be built in the LSI, is set as the threshold value. Moreover, the low-voltage detection device may also be built in one LSI, including other components of this low-voltage detection device.

Furthermore, the CPU 37 sets, in the flash memory 38, the threshold value of the voltage by which to reset the LSI, thereby making it possible to set a plurality of threshold values of the voltage for detecting the low-voltage detection in the single LSI. Accordingly, there is no necessity of manufacturing the LSIs respectively for the LSI applications and for the utilizable power source voltages.

<Example of Configuration of D/A Converter>

The D/A converter 39 according to the third embodiment of the present invention will hereinafter be described with reference to the drawing in FIG. 6. The D/A converter 39 includes resistances 47-50 connected to the comparative voltage Vref, a resistance 51 connected to the resistance 47, a resistance 52 connected to the resistance 48, a resistance 53 connected to the resistance 49, a resistance 54 connected to the resistance 50, and an analog switch 55 connected to the resistances 47-55. The analog switch 55 has switches 56-59. The resistance 47 shall be set as a resistance having a magnitude of 5R, the resistance 48 shall have a magnitude of 4R, the resistance 49 shall have a magnitude of 3R, the resistance 50 shall have a magnitude of 2R, the resistance 51 shall have a magnitude of 5R, the resistance 52 shall have a magnitude of 6R, the resistance 53 shall have a magnitude of 7R, and the resistance 54 shall have a magnitude of 8R.

A voltage between the resistance 47 and the resistance 51 is set as V5. The voltage V5 is a voltage having a magnitude that is 5/10 the comparative voltage Vref (1.2V). Therefore, when switching ON the switch 56, a voltage (0.6V) having a magnitude that is 5/10 the comparative voltage Vref is inputted to the comparator 42.

A voltage between the resistance 48 and the resistance 52 is set as V6. The voltage V6 is a voltage having a magnitude that is 6/0 the comparative voltage Vref. Therefore, when switching ON the switch 57, a voltage (0.72V) having a magnitude that is 6/10 the comparative voltage Vref is inputted to the comparator 42.

A voltage between the resistance 49 and the resistance 53 is set as V7. The voltage V7 is a voltage having a magnitude that is 7/10 the comparative voltage Vref. Hence, when switching ON the switch 58, a voltage (0.84V) having a magnitude that is 7/10 the comparative voltage Vref is inputted to the comparator 42.

A voltage between the resistance 50 and the resistance 54 is set as V8. The voltage V8 is a voltage having a magnitude that is 8/10 the comparative voltage Vref. Therefore, when switching ON the switch 59, a voltage (0.96V) having a magnitude that is 8/10 the comparative voltage Vref is inputted to the comparator 42.

The analog switch 55 switches ON any one of the switches 55 through 59 and switches OFF the remaining switches on the basis of the detection pattern inputted from the flash memory 38. For example, when the detection pattern inputted from the flash memory 38 is [HLLL], the analog switch 55 switches ON the switch 56. With this operation, the voltage of 0.6V is outputted to the comparator 42 from the D/A converter 39. Further, when the detection pattern inputted from the flash memory 38 is [LHLL], the analog switch 55 switches ON the switch 57. With this operation, the voltage of 0.72V is outputted to the comparator 42 from the D/A converter 39. Moreover, when the detection pattern inputted from the flash memory 38 is [LLHL], the analog switch 55 switches ON the switch 58. With this operation, the voltage of 0.84V is outputted to the comparator 42 from the D/A converter 39. Still further, when the detection pattern inputted from the flash memory 38 is [LLLH], the switch 59 is switched ON. With this operation, the voltage of 0.96V is outputted to the comparator 42 from the D/A converter 39. Thus, the D/A converter 39 can output the voltage corresponding to the detection pattern inputted from the flash memory 38.

In a case where the flash memory 38 is stored with the detection pattern [HLLL], the voltage of 0.6V is outputted from the D/A converter 39. In this case, the comparator 42 outputs the signal [H] to the signal integrator 45 when the voltage V (=Vcc/5) is equal to or larger than 0.6V, and outputs the signal [L] to the signal integrator 45 when the voltage V is smaller than 0.6V.

In a case where the flash memory 38 is stored with the detection pattern [LHLL], the voltage of 0.72V is outputted from the D/A converter 39. In this case, the comparator 42 outputs the signal [H] to the signal integrator 45 when the voltage V (=Vcc/5) is equal to or larger than 0.72V, and outputs the signal [L] to the signal integrator 45 when the voltage V is smaller than 0.72V.

In a case where the flash memory 38 is stored with the detection pattern [LLHL], the voltage of 0.84V is outputted from the D/A converter 39. In this case, the comparator 42 outputs the signal [H] to the signal integrator 45 when the voltage V (=Vcc/5) is equal to or larger than 0.84V, and outputs the signal [L] to the signal integrator 45 when the voltage V is smaller than 0.84V.

In a case where the flash memory 38 is stored with the detection pattern [LLLH], the voltage of 0.96V is outputted from the D/A converter 39. In this case, the comparator 42 outputs the signal [H] to the signal integrator 45 when the voltage V (=Vcc/5) is equal to or larger than 0.96V, and outputs the signal [L] to the signal integrator 45 when the voltage V is smaller than 0.96V.

<Concerning Registerable Count of Threshold Values of Voltage>

On such an occasion that the CPU 37 registers the threshold value of the voltage in the flash memory 38, a registerable count thereof depends on a pattern count (the number of patterns) of the magnitudes of the voltage outputted from the D/A converter 39. Considered is, for example, a case in which the pattern count of the magnitudes of the voltage outputted from the D/A converter 39 to the comparator 42 is “3”. In this case, up to three pieces of magnitudes of the voltage can be registered in the flash memory 38. Considered next is a case in which the pattern count of the magnitudes of the voltage outputted from the D/A converter 39 to the comparator 42 is “4”. In this case, up to four pieces of magnitudes of the voltage can be registered in the flash memory 38. Thus, as the pattern count of the magnitudes of the voltage outputted from the D/A converter 39 to the comparator 42 becomes larger, the registerable count of the threshold values of the voltage gets greater.

### INCORPORATION BY REFERENCE

The disclosures of Japanese patent application No. JP2005-370192 filed on Dec. 22, 2005 including the specification, drawings and abstract are incorporated herein by reference.

What is claimed is:

1. A low-voltage detection device comprising:
a registering unit registering, as digital data, a threshold value serving as a reference for judging a decrease in power source voltage supplied to a semiconductor device;
a detection data outputting unit executing an analog/digital conversion of the power source voltage, and outputting detection data corresponding to a magnitude of the power source voltage; and
a control unit comparing the threshold value with the detection data, and outputting a control signal for controlling as to whether or not setting of the semiconductor device should be set in an initial state in accordance with the compared result.

2. A low-voltage detection device comprising:
a registering unit registering, as digital data, a threshold value serving as a reference for judging a decrease in power source voltage supplied to a semiconductor device;
a voltage outputting unit executing an analog/digital conversion of the threshold value, and outputting a voltage corresponding the threshold value; and
a control unit comparing the voltage corresponding to the threshold value with the power source voltage, and outputting a control signal for controlling as to whether or not setting of the semiconductor device should be set in an initial state in accordance with the compared result.

3. The low-voltage detection device according to claim 1, further comprising a second control unit outputting a second control signal that sets the setting of the semiconductor device in the initial state for a predetermined period of time from just after power-on of the power source voltage and gets the setting of the semiconductor device transitioning from the initial state after the predetermined period of time.

4. The low-voltage detection device according to claim 1, further comprising a third control unit detecting the power source voltage and outputting a signal that sets, when the detected power source voltage does not reach a predetermined value, the setting of the semiconductor device in the initial state independently of the control signal by the control unit.

5. The low-voltage detection device according to claim 1, further comprising a fourth control unit accepting one or more inputs of the signals that control as to whether or not the setting of the semiconductor device should be set in the initial state and outputting, when one of the accepted signals is a signal that sets the setting of the semiconductor device in the initial state, the signal that sets the setting of the semiconductor device in the initial state.

6. The low-voltage detection device according to claim 1, further comprising:
a inputting unit inputting the signal that controls as to whether or not the setting of the semiconductor device should be set in the initial state;
a unit setting the setting of the semiconductor device in the initial state when the signal inputted by the inputting unit is the signal that sets the setting of the semiconductor device in the initial state and when the setting of the semiconductor device is not in the initial state;
a unit continuing the initial state of the semiconductor device when the signal inputted by the inputting unit is the signal that sets the setting of the semiconductor device in the initial state and when the setting of the semiconductor device is in the initial state;
a unit continuing the setting of the semiconductor device when the signal inputted by the inputting unit is a signal other than the signal that sets the setting of the semiconductor device in the initial state and when the setting of the semiconductor device is not in the initial state; and
a unit canceling the initial state of the semiconductor device when the signal inputted by the inputting unit is the signal other than the signal that sets the setting of the semiconductor device in the initial state and when the setting of the semiconductor device is in the initial state.

7. A low-voltage detection method comprising:
a registering step of registering, as digital data, a threshold value serving as a reference for judging a decrease in power source voltage supplied to a semiconductor device;
a detection data outputting step of executing an analog/digital conversion of the power source voltage, and outputting detection data corresponding to a magnitude of the power source voltage; and
a control step of comparing the threshold value with the detection data, and outputting a control signal for controlling as to whether or not setting of the semiconductor device should be set in an initial state in accordance with the compared result.

8. A low-voltage detection method comprising:
a registering step of registering, as digital data, a threshold value serving as a reference for judging a decrease in power source voltage supplied to a semiconductor device;
a voltage outputting step of executing an analog/digital conversion of the threshold value, and outputting a voltage corresponding the threshold value; and
a control step of comparing the voltage corresponding to the threshold value with the power source voltage, and controlling as to whether or not setting of the semiconductor device should be set in an initial state in accordance with the compared result.

9. The low-voltage detection method according to claim 7, further comprising a second control step of outputting a signal that sets the setting of the semiconductor device in the initial state for a predetermined period of time from just after power-on of the power source voltage and outputting a signal that gets the setting of the semiconductor device transitioning from the initial state after the predetermined period of time.

10. The low-voltage detection method according to claim 7, further comprising a third control step of detecting the power source voltage and outputting a signal that sets, when the detected power source voltage does not reach a predetermined value, the setting of the semiconductor device in the initial state independently of the control step.

11. The low-voltage detection method according to claim 7, further comprising a fourth control step of accepting one or more inputs of the signals that control as to whether or not the setting of the semiconductor device should be set in the initial state and outputting, when one of the accepted signals is a signal that sets the setting of the semiconductor device in the initial state, the signal that sets the setting of the semiconductor device in the initial state.

12. The low-voltage detection method according to claim 7, further comprising:
an inputting step of inputting the signal that controls as to whether or not the setting of the semiconductor device should be set in the initial state;
a step of setting the setting of the semiconductor device in the initial state when the signal inputted in the inputting step is the signal that sets the setting of the semiconductor device in the initial state and when the setting of the semiconductor device is not in the initial state;
a step of continuing the initial state of the semiconductor device when the signal inputted in the inputting step is the signal that sets the setting of the semiconductor device in the initial state and when the setting of the semiconductor device is in the initial state;
a step of continuing the setting of the semiconductor device when the signal inputted in the inputting step is a signal other than the signal that sets the setting of the semiconductor device in the initial state and when the setting of the semiconductor device is not in the initial state; and
a step of canceling the initial state of the semiconductor device when the signal inputted in the inputting step is the signal other than the signal that sets the setting of the semiconductor device in the initial state and when the setting of the semiconductor device is in the initial state.
